(19) United States
(12) Patent Application Publication
(10) Pub. No.: US 2009/0125761 A1
(43) Pub. Date: May 14, 2009

(54) Method for controlling a DRAM

(76) Inventors: Wen-Min Lu, Hsinchu City (TW); Bin-Feng Hung, Taipei City (TW); Ming-Sung Huang, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/116,208

(22) Filed: May 7, 2008

(30) Foreign Application Priority Data
Nov. 14, 2007 (TW) 096142997

(51) Int. Cl. G11C 29/04

(52) U.S. Cl. 714/718; 714/E11.159

(57) ABSTRACT

A method for controlling a DRAM includes detecting failed memory cells of the DRAM, recording the rows corresponding to the failed memory cells, receiving a control signal for accessing the memory cell with column address X and row address Y, determining if the row address Y is in the recorded failed rows list, and if yes, replacing the memory cell to be accessed with the memory cell with the column address X and row address Z which is not same as Y.

### BACKGROUND OF THE INVENTION

1. Field of the Invention

The present invention relates to a method for controlling a Dynamic Random Access Memory (DRAM), and more particularly, to a method for controlling a DRAM by detecting defect memory cells and replacing the detected defect memory cells with other good memory cells.

2. Description of the Prior Art

Please refer to FIG. 1. FIG. 1 is a flowchart illustrating a conventional method 100 for controlling a DRAM. The steps are described as follows.

Step 110: Start;

Step 120: Accessing a memory cell of the DRAM according to a control command;

Step 130: The DRAM reads data from the accessed memory cell, or writes data to the accessed memory cell;

Step 140: End.

In step 120, the control command comprises a reading command or a writing command, and the address of the accessed memory cell. Generally, a DRAM is composed of a memory cell array constructed with M columns and N rows. Therefore, the address of the accessed memory cell indicates the location of the column and the row of the accessed memory cell in the memory array, which enables the data access procedure to be accomplished.

However, after the DRAM is used for a period of time, defect memory cells are generated. If the external control command reads from the defect memory cell, the read data is incorrect, and if the external control command writes to the defect memory cell, the data is not able to be stored in the defect memory cell. Conventionally, the DRAM with defect memory cells is viewed as a defect DRAM and is abandoned, even though there are other good memory cells in the DRAM. In this way, those good memory cells are wasted.

### SUMMARY OF THE INVENTION

The present invention provides a method for controlling a DRAM. The DRAM comprises a memory array constructed by memory cells of M columns and N rows. The method comprises detecting defect memory cells of the DRAM, recording corresponding rows of the detected defect memory cells, receiving a control command for accessing a memory cell located in X column and Y row of the DRAM, detecting if the Y row is in the recorded rows of the detected defect memory cells, and accessing a memory cell located in X column and Z row of the DRAM according to the control command and the detecting result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart illustrating a conventional method for controlling a DRAM.

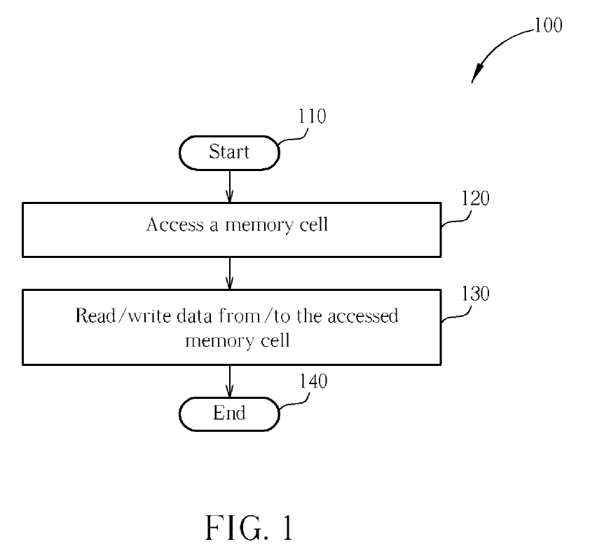

FIG. 2 is a flowchart illustrating a method for controlling a DRAM according to a first embodiment of the present invention.

### DETAILED DESCRIPTION

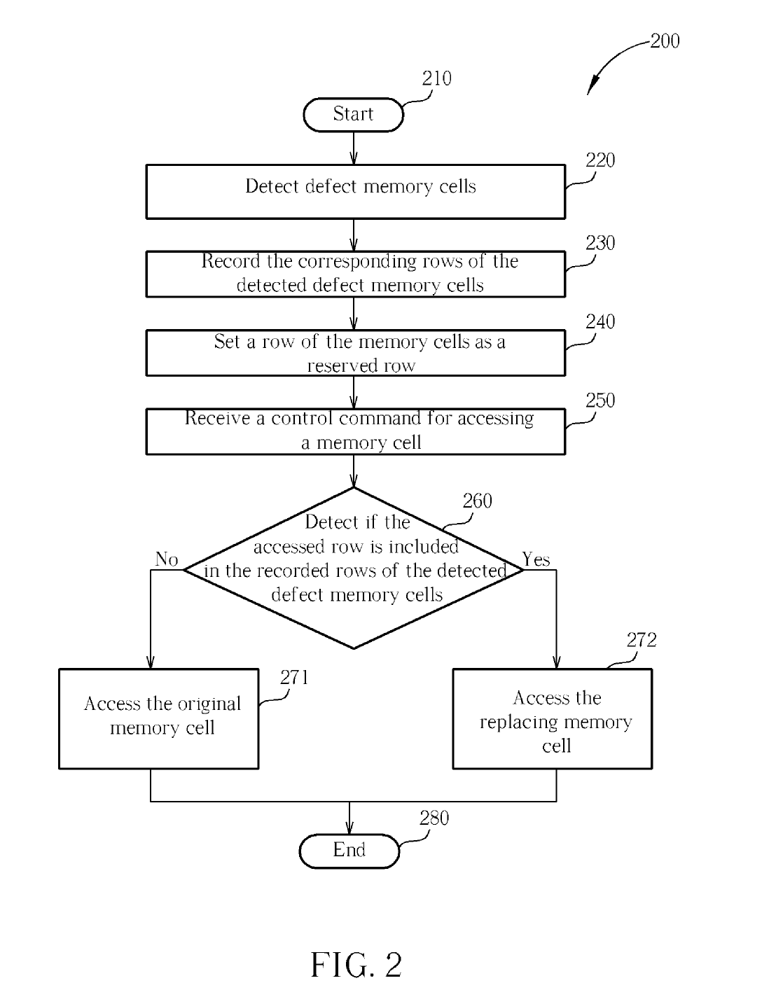

Please refer to FIG. 2. FIG. 2 is a flowchart illustrating a method 200 for controlling a DRAM according to a first embodiment of the present invention. The steps are described as follows.

Step 210: Start;

Step 220: Detect defect memory cells of the DRAM;

Step 230: Record the corresponding rows of the detected defect memory cells;

Step 240: Set a row of the memory cells as a reserved row Z of memory cells;

Step 250: Receive a control command for accessing a memory cell located at the column X and the row Y of the DRAM;

Step 260: Detect if the row Y is included in the recorded rows of the detected defect memory cells; if so, go to step 272; if not, go to step 271;

Step 271: Access the memory cell located at the column X and the row Y of the DRAM, Go to Step 280;

Step 272: Access the memory cell located at the column X and the row Z of the DRAM;

Step 280: End.

In step 220, detecting the defect memory cells of the DRAM is achieved by scanning all the memory cells of the DRAM and then determining defect memory cells and good memory cells from the scanned cells. Determining a memory cell being a defect memory cell is achieved by writing data to a memory cell and then reading the stored data from the memory cell. If the data read does not match, the memory cell is determined as a defect memory cell.

In step 230, the corresponding rows of the defect memory cells is recorded. For example, if there are 3 defect memory cells respectively located at column 1 and row 2, column 2 and row 3, and column 3 and row 4, then the rows 2, 3, and 4 are recorded, which means in rows 2, 3, and 4, defect memory cells exist, and the recorded rows are abandoned. When the DRAM receives a control command for accessing memory cells located in those recorded rows, the DRAM does not access the memory cells located in those recorded rows. Instead, the DRAM accesses the memory cells in the reserved rows in step 240 according to a predetermined relation between the memory cells in those recorded rows and the reserved rows. In this way, the DRAM does not access defect memory cells.

In step 240, the reserved row memory cells are reserved for replacing the defect memory cells. The reserved row memory cells can be designated with the last few rows of the DRAM (at least one row). It is because, on general, the DRAM is not 100% used, which means that the last few rows of memory cells are seldom used and can be set as reserved for replacing the defect memory cells. Furthermore, the reserved row memory cells can be decided after the determining the defect memory cells, which ensures the memory cells in the reserved rows are all good, and increases data integrity.

Additionally, the number of the reserved rows of the memory cells can be set at a fixed number. For example, if the last 5 rows of the DRAM are seldom used, then the last 5 rows of the memory cells can be set as reserved row memory cells and the fixed number is 5. The number of the reserved rows of the memory cells can be set according to the number of the recorded rows of the defect memory cells. For example, if the number of the recorded rows of the defect memory cells is 10, then the number of the reserved rows of the memory cells is 10 accordingly. In this way, it is avoided that the number of the recorded rows of the defect memory cells is bigger than the number of the reserved rows of the memory cells and data access is still possibly incorrect.

Additionally, the relation between the rows of the defect memory cells and the reserved rows of the memory cells can be designed as desired. For example, the row 2 of the defect memory cells can be correlated to the reserved row 10 of the memory cells, the row 4 of the defect memory cells can be correlated to the reserved row 18 of the memory cells. The rule can be sequentially or not, and is determined by the user.

In step 260, it is determined if the accessed memory cell is in the row of the recorded rows of the defect memory cells. If the accessed memory cell is in the row of the recorded rows of the defect memory cells, the row address of the accessed memory cell is changed to the corresponding row address in the reserved rows of the memory cells and the column address of the accessed memory cell keeps the same, which is executed in the step 272. If the accessed memory cell is not in the row of the recorded rows of the defect memory cells, then the accessed memory cell is directly accessed according to the control command. Therefore, the defect memory cells are not accessed and incorrect data is avoided.

To sum up, the method for controlling a DRAM of the present invention efficiently accesses the DRAM while some of the memory cells of the DRAM are defect memory cells instead of abandoning the DRAM as the prior art, which not only increases the lifespan of the DRAM but also saves cost for users.

Those skilled in the art will readily observe that numerous modifications and alterations of the device and method may be made while retaining the teachings of the invention.

What is claimed is:

1. A method for controlling a DRAM, the DRAM comprising a memory array constructed by memory cells of M columns and N rows, the method comprising:
detecting defect memory cells of the DRAM;
recording corresponding rows of the detected defect memory cells;
receiving a control command for accessing a memory cell located in an X column and a Y row of the DRAM;
detecting if the Y row is in the recorded rows of the detected defect memory cells; and
accessing a memory cell located in the X column and a Z row of the DRAM according to the control command and the detecting result.

2. The method of claim 1 further comprising setting at least one row of memory cells as reserved row memory cells.

3. The method of claim 2 wherein accessing a memory cell located in the X column and the Z row of the DRAM according to the control command and the detecting result comprises when the Y row is not in the recorded rows of the detected defect memory cells, accessing the memory cell located in the X column and the Y row of the DRAM according to the control command.

4. The method of claim 2 wherein accessing a memory cell located in the X column and the Z row of the DRAM according to the control command and the detecting result comprises when the Y row is in the recorded rows of the detected defect memory cells, accessing the memory cell located in the X column and the Z row of the DRAM according to the control command and Z is not equal to Y.

5. The method of claim 4 wherein the memory cells of the Z row is included in the reserved row memory cells.

6. The method of claim 2 wherein setting at least one row of memory cells as reserved row memory cells comprises setting at least one row of memory cells as reserved row memory cells according to the recorded rows of the detected defect memory cells for ensuring the reserved row memory cells from being defect.

7. The method of claim 2 wherein setting at least one row of memory cells as reserved row memory cells comprises setting at least one row of memory cells with lower possibility of being used as reserved row memory cells.

8. The method of claim 2 wherein setting at least one row of memory cells as reserved row memory cells comprises setting number of rows of memory cells as reserved row memory cells according to number of the recorded rows of the detected defect memory cells.
